(19) United States
(12) Patent Application Publication
(10) Pub. No.: US 2010/0304013 A1
(43) Pub. Date: Dec. 2, 2010

(54) Touch Panel Manufacturing Method

(76) Inventor: Xuei-Min WANG, Chung U (TW)

Correspondence Address: LanWay IPR Services, P.O. Box 220746, Chantilly, VA, 20153, US

(21) Appl. No.: 12/476,252

(22) Filed: Jun. 1, 2009

(51) Int. Cl. B05D 5/12; C23C 14/34

(52) U.S. Cl. 427/58; 204/192.1

(57) ABSTRACT

In a touch panel manufacturing method, a substrate is prepared, a sensing layer and a protective layer are sequentially formed on the substrate, an electrode layer with spaced electrodes is formed by firing, and the electrode layer is penetrated through the protective layer and formed on a surface of the sensing layer. Since the sensing layer is covered by the protective layer before forming the electrode layer, the sensing layer can be avoided to be influenced by accompanying heat, chemical substances and/or oxygen gas, its intrinsic physical characteristics are retained and its periphery would not be damaged. Moreover, since the formation of the protective layer is prior to the electrode layer, the height difference formed at the periphery of the electrode layer and the optical interference phenomena both are prevented. Finally, the manufacturing process is simplified and thus production speed and production capacity are increased.

### BACKGROUND

1. Technical Field

The present invention generally relates to manufacturing methods and, particularly to a touch panel manufacturing method with simplified manufacturing process.

2. Description of the Related Art

Nowadays, with the rapid development of high-tech electronic information industry, consumer electronic products have become necessities of people's daily lives. Many consumer electronic products are continuingly moving toward the lightweight, thin, short and small trends and especially for a touch-sensitive liquid crystal display panel combined with information display and information input technologies. The touch-sensitive liquid crystal display panel is endowed with a liquid crystal display function as well as a touch-sensitive input function, and thus the practicability of the various consumer electronic products can be greatly enhanced. The touch-sensitive liquid crystal display panel predominantly is that combining a touch panel onto a liquid crystal display panel and using a control circuit to integrate the display of the liquid crystal display panel with a touch-sensitive area corresponding to a surface of the touch panel.

Many types of touch panels are known, which include the resistive type, capacitive type, ultrasonic surface acoustic wave type, optical (infrared) type, and so on. Among these types, the resistive type is the most widely used, and the capacitive type is followed. The capacitive type touch panel has its advantages of waterproof, scratch resistant, high transmittance and wide applicable temperature range. Although the capacitive type touch panel has a relatively high price, it is gradually moving in the small-size touch panel market along with increasing technology maturity thereof.

Referring to FIG. 1, showing a flow diagram of a conventional capacitive type touch panel manufacturing method. As illustrated in FIG. 1, the capacitive type touch panel 1 has a transparent substrate 10 and a sensing layer 11 formed on a surface of the substrate 10. The sensing layer 11 has an electrode layer 12 with spaced electrodes formed on a surface thereof. The electrode layer 12 is made of metal such as copper or aluminum. The formation of the electrode layer 12 on the surface of the sensing layer 11 can be performed by a method selected from the group consisting of dip coating, embossing, sputtering, evaporation, chemical vapor deposition, screen printing and pad printing. Finally, a protective layer 12 is formed to cover surfaces of the sensing layer 11 and the electrode layer 12, and the manufacture of the capacitive type touch panel 1 is completed accordingly.

However, in the manufacturing process of the capacitive type touch panel 1, several drawbacks are existed as follows.

In one aspect, during the formation of the metallic electrode layer 12 on the surface of the sensing layer 11, a large quantity of heat or chemical substances would accompany therewith, which would easily result in the physical characteristics of the sensing layer 11 being damaged, e.g., the changes of electrical conductivity, electrical resistance, etc. Therefore, when the capacitive type touch panel is in use, the deficiency of wrong-detection or inaccurate touch detection would be easily occurred.

In another aspect, in the post-process for forming the protective layer 13, a high-temperature sputtering process is necessary to form the protective layer 13 on the surfaces of the sensing layer 11 and the electrode layer 12, when gases accompanying with the high-temperature sputtering process flow across the electrode layer 12, an oxidation phenomena would be easily occurred at the surface of the electrode layer 12 and thus the electrical resistance or electrical conductivity of the electrode layer 12 would be influenced.

In still another aspect, since the protective layer 13 is formed after the formation of the electrode layer 12 with spaced electrodes, the protective layer 13 would not evenly cover the sensing layer 11 and the electrode layer 12 and thus a height difference of the protective layer 13 formed at the periphery of the electrode layer 12 would be easily generated. Accordingly, the electrode layer 13 would be easily damaged in use, and even the height difference would cause an optical interference issue.

In even still another aspect, when the capacitive type touch panel 1 is in manufacturing, manufacturing steps are too complicated. In particular, it is necessary to firstly form the sensing layer 11 on the substrate 10, and subsequently form the whole planar electrode layer 12. In order to form the spaced electrodes of the electrode layer 12, an etching step is necessarily required to remove unwanted portions of the electrode layer 12. Finally, the protective layer 13 is formed for covering. However, processes for the above-mentioned steps are not the same and required manufacture machines also are not the same, which results in the entire manufacturing process being too complicated.

### BRIEF SUMMARY

The present invention provides a touch panel manufacturing method with simplified manufacturing process.

The present invention further provides a touch panel manufacturing method which would not damage physical characteristics of touch panel.

In order to achieve the above-mentioned advantages, a touch panel manufacturing method in accordance with an embodiment of the present invention includes the following steps of: preparing a substrate; sequentially forming a sensing layer and a protective layer on a surface of the substrate in that order; forming an electrode layer with spaced electrodes by a firing process; and the electrode layer being penetrated through the protective layer and formed on a surface of the sensing layer.

Among the above-mentioned steps, on the surface of the substrate, the sensing layer is firstly formed and the protective layer is formed thereafter. Such an arrangement can avoid the sensing layer to be surface oxidized resulting from long-time exposure to air. Since the electrode layer is made of metal such as aluminum or copper, the formation of the electrode layer can be performed by the firing process in which: liquid or semi-liquid metal is instantly melted and penetrates through the protective layer and then spaced electrodes are formed on the surface of the sensing layer in the form of layer.

In the above-mentioned touch panel manufacturing method, the sensing layer is covered by the protective layer ahead, and a large quantity of heat or chemical substances accompanying with the formation of the electrode layer would not influence physical characteristics of the sensing layer. Therefore, the sensing layer can retain better physical characteristics such as electrical conductivity or electrical resistance, etc. Furthermore, since the formation of the protective layer is prior to the formation of the electrode layer, a contact area between the electrode layer and air can be reduced, the surface oxidization phenomenon of the electrode layer can be avoided and thus the electrode layer can achieve better physical characteristics such as electrical conductivity or electrical resistance. Meanwhile, such an arrangement of the formation of the sensing layer prior to the formation of the electrode layer, compared with the arrangement of the formation of the electrode layer prior to the formation of the sensing layer in the prior art, the height difference of the protective layer at the periphery of the electrode layer can be effectively prevented and the occurrence of optical interference phenomena can be avoided.

In addition, in term of process simplification, since the processes for the formation of both the sensing layer and the protective layer are similar to each other, the sensing layer and the protective layer can be sequentially formed on the substrate in a same process. Meanwhile, the formation of the electrode layer with spaced electrodes can be completed only by one time firing process, so that increased production speed and production capacity with respect to the prior art can be achieved.

In another embodiment of the present invention, the touch panel manufacturing method in accordance with the present invention is not limited to a single surface of the substrate having the sensing layer, the protective layer and the electrode layer formed thereon, and can be dual surfaces of the substrate each having such the sensing layer, protective layer and electrode layer formed thereon.

In particular, the touch panel manufacturing method for dual-sided manufacturing includes the steps of: preparing a substrate; forming a first sensing layer and a second sensing layer respectively on a first surface and a second surface of the substrate; forming a first protective layer and a second protective layer respectively on the first sensing layer and the second sensing layer; forming a first electrode layer with spaced electrodes and a second electrode layer with spaced electrodes by a firing process; and the first electrode layer and the second electrode layer respectively being penetrated through the first protective layer and the second protective layer and formed on a surface of the first sensing layer and a surface of the second sensing layer.

Among these steps, firstly, the first sensing layer and the second sensing layer respectively are formed on the first surface and the second surface of the substrate, and subsequently the first protective layer and the second protective layer respectively are formed on the first sensing layer and the second sensing layer. Then the first electrode layer and the second electrode layer respectively are formed on the surfaces of the first sensing layer and the second sensing layer by the firing process in which: liquid or semi-liquid metal is instantly melted and penetrates through the first protective layer and the second protective layer. The first electrode layer and the second electrode layer are configured with spaced electrodes.

In still another embodiment of the present invention, except for the above-mentioned touch panel manufacturing method being used for dual-sided manufacturing, another touch panel manufacturing method used for dual-sided manufacturing is provided and includes the steps of: preparing a substrate; sequentially forming a first sensing layer and a first protective layer on a first surface of the substrate in that order; forming a first electrode layer with spaced electrodes by a firing process; the first electrode layer being penetrated through the first protective layer and formed on a surface of the first sensing layer; sequentially forming a second sensing layer and a second protective layer on a second surface of the substrate in that order; forming a second electrode layer with spaced electrodes by a firing process; and the second electrode layer being penetrated through the second protective layer and formed on a surface of the second sensing layer.

Among these steps, firstly, the first sensing layer, the first protective layer and the first electrode layer are sequentially formed on the first surface of the substrate, and subsequently the second sensing layer, the second protective layer and the second electrode layer are sequentially formed on the second surface of the substrate.

Regardless of which one of the above-mentioned touch panel manufacturing methods, all of them can achieve the following advantages that: the first sensing layer and the second sensing layer are avoided to be surface oxidized resulting from long-time exposure to air in post-process. Meanwhile, during the formation of the first electrode layer and the second electrode layer, the physical characteristics of the first sensing layer and the second sensing layer are not influenced. Furthermore, after the formation of the first protective layer and the second protective layer, no optical interference phenomena occur.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a flow diagram of a conventional capacitive type touch panel manufacturing method.

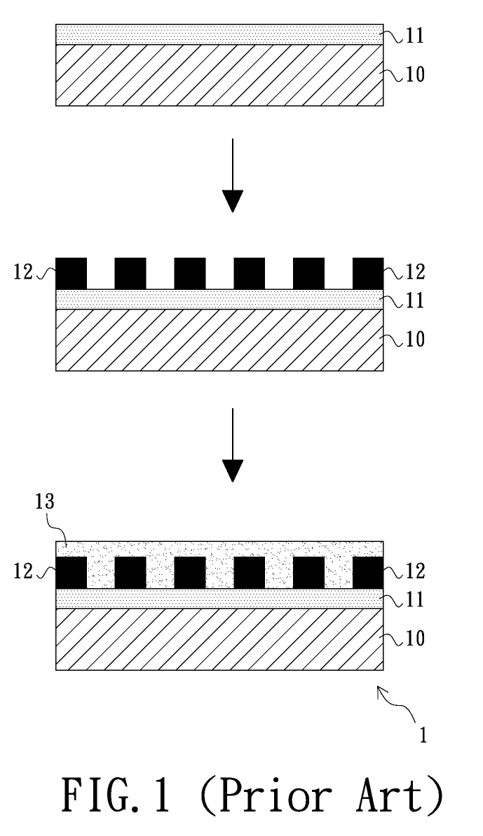

FIG. 2 is a flow art of a touch panel manufacturing method in accordance with a preferred embodiment of the present invention.

FIG. 3 is a flow diagram (1) of the touch panel manufacturing method in FIG. 2.

FIG. 4 is a flow diagram (2) of the touch panel manufacturing method in FIG. 2.

FIG. 5 is a flow art of a touch panel manufacturing method in accordance with another preferred embodiment of the present invention.

FIG. 6 is a flow diagram (1) of the touch panel manufacturing method in FIG. 5.

FIG. 7 is a flow diagram (2) of the touch panel manufacturing method in FIG. 5.

FIG. 8 is a flow art of a touch panel manufacturing method in accordance with still another preferred embodiment of the present invention.

FIG. 9 is a flow diagram (1) of the touch panel manufacturing method in FIG. 8.

FIG. 10 is a flow diagram (2) of the touch panel manufacturing method in FIG. 8.

### DETAILED DESCRIPTION

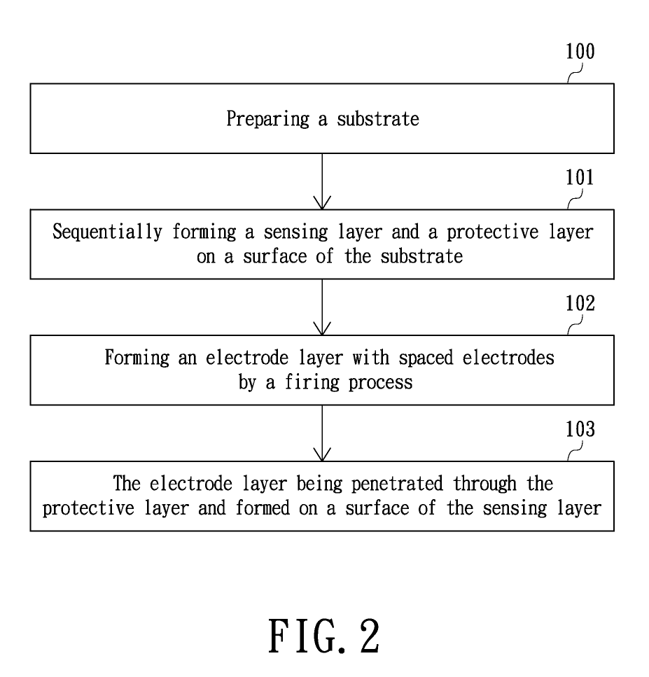

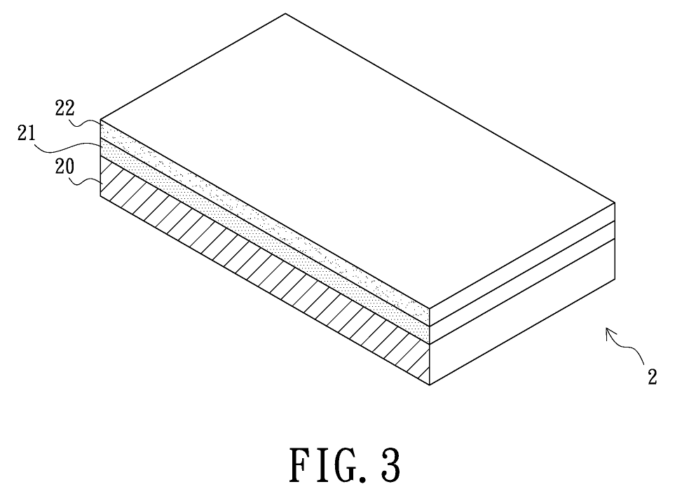

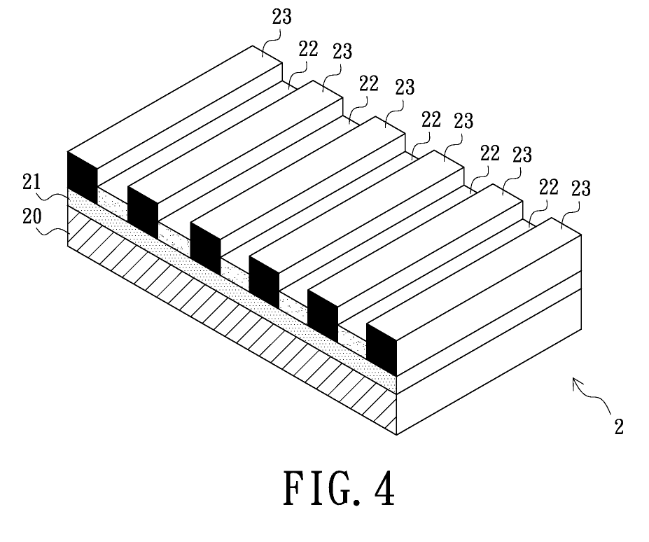

Referring to FIGS. 2 through 4, respectively illustrating a flow chart, a flow diagram (1) and a flow diagram (2) of a touch panel manufacturing method in accordance with a preferred embodiment of the present invention. The touch panel manufacturing method includes several steps as follows.

A substrate is prepared (Step 100). The substrate 20 may be made of glass and is for supporting the touch panel 2, so that the touch panel 2 has a particular hardness and facilitates in combination with an external electronic device.

A sensing layer and a protective layer are sequentially formed on a surface of the substrate 20 in that order (Step 101). The sensing layer 21 may be made of indium tin oxide (ITO). The protective layer 22 may be made of cyclo-olefin copolymer (COC), polyethylene terephthalate (PET), silicon dioxide (SiO2) or plastic, etc. The formation of the sensing layer 21 and the protective layer 22 on the surface of the substrate 20 can be performed by a method selected from the group consisting of dip coating, embossing, sputtering, evaporation, chemical vapor deposition, screen printing and pad printing. After the formation of the sensing layer 21 on the substrate 20, the sensing layer 21 is instantly covered by the protective layer 22, which can protect the surface and edges of the sensing layer 21 from being damaged and avoid the occurrence of optical interference phenomena, besides can prevent the sensing layer 21 from surface oxidation in post-process resulting from long-time exposure to air.

An electrode layer with spaced electrodes is formed by a firing process (Step 103).

The electrode layer is penetrated through the protective layer and formed on a surface of the sensing layer (Step 104). The electrode layer 23 may be made of metal such as copper or aluminum. The formation of the electrode layer 23 is performed by firing such as extrusion, injection, etc., in which liquid or semi-liquid metal are directly arranged on the surface of the protective layer 22 in a spaced manner and at the moment the liquid or semi-liquid metal flows downwardly to melt the protective layer 22 until contacts the sensing layer 21 at the bottom of the protective layer 22.

In one aspect, since the surface of the sensing layer 21 is covered by the protective layer 22 in advance, the sensing layer 21 can be avoided to be damaged, e.g., oxidized or chemical substances adhered thereto, during the formation of the electrode layer 23. Therefore, the sensing layer 21 can retain its intrinsic physical characteristics such as electrical resistance, electrical conductivity and the touch detection accuracy of the touch panel 2 is not influenced.

In another aspect, since the processes for the formation of the sensing layer 21 and the protective layer 22 are similar to each other, the sensing layer 21 and the protective layer 22 can be sequentially formed on the surface of the substrate 20 in the same process. Meanwhile, the formation of the electrode layer 23 with spaced electrodes can be completed only by one time firing process, so that increased production speed and production capacity with respect to the prior art can be achieved.

It is indicated that, in the above-mentioned embodiment, the electrode layer 23 may be consisted of electrodes in the form of electrode strips arranged in a spaced manner, or in the form of electrode blocks arranged in matrix or array. In the above illustrated embodiment, the electrode layer 23 is consisted of electrode strips arranged in a spaced manner for the purpose of illustration.

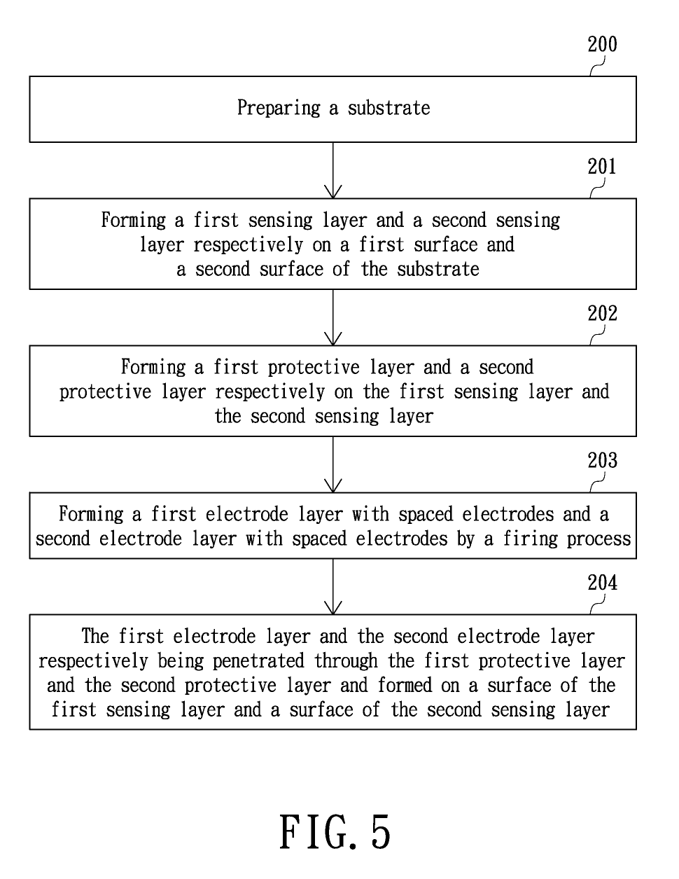

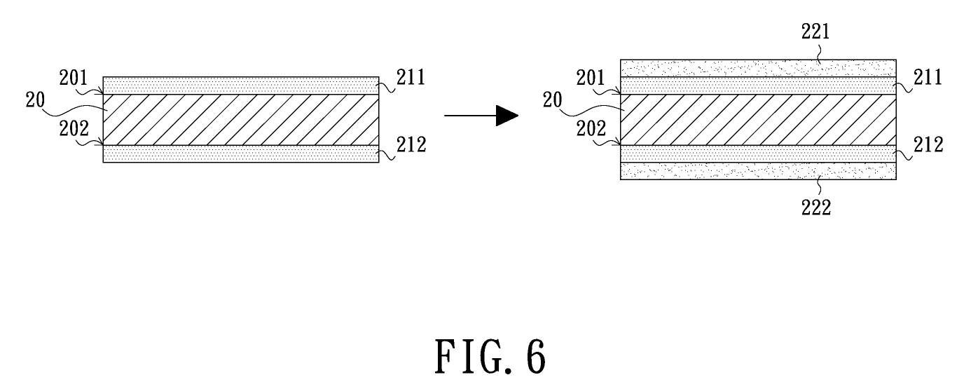

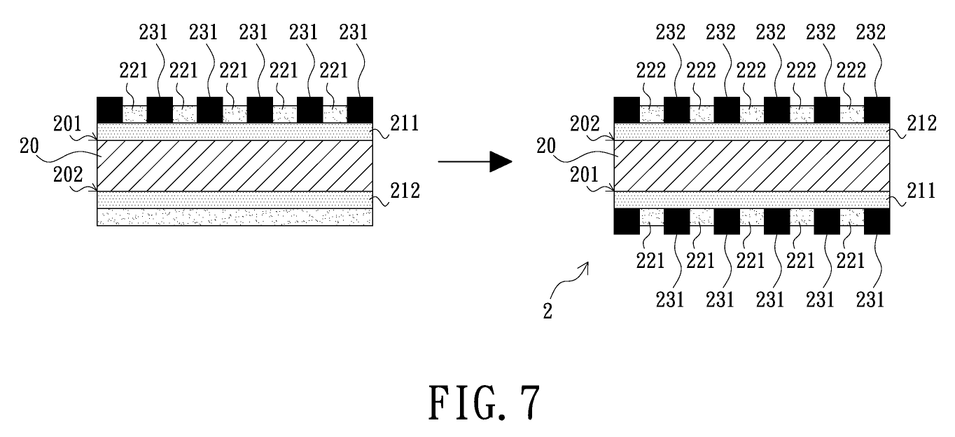

Referring to FIGS. 5 through 7, respectively illustrating a flow chart, a flow diagram (1) and a flow diagram (2) of a touch panel manufacturing method in accordance with another preferred embodiment of the present invention. The touch panel manufacturing method in the present embodiment is used for dual-sided manufacturing, rather than single-sided manufacturing as illustrated in FIGS. 2 through 4. In particular, the touch panel manufacturing method in accordance with the present embodiment includes several steps as follows.

A substrate is prepared (Step 200). The substrate 20 may be made of glass and is for supporting the touch panel 2, so that the touch panel 2 has a particular hardness. The substrate 20 has a first surface 201 and a second surface 202.

A first sensing layer and a second sensing layer are respectively formed on the first surface and the second surface of the substrate (Step 201). The first sensing layer 211 and the second sensing layer 212 may be made of indium tin oxide (ITO) and formed by any one method selected from the group consisting of dip coating, embossing, sputtering, evaporation, chemical vapor deposition, screen printing and pad printing. Therefore, the first sensing layer 211 can be formed on the first surface 201 by any one of the methods, and likewise, the second sensing layer 212 can be formed on the second surface 202 by any one of the methods.

A first protective layer and a second protective layer respectively are formed on the first sensing layer and the second sensing layer (Step 202). The first protective layer 221 and the second protective layer 222 may be made of cyclo-olefin copolymer (COC), polyethylene terephthalate (PET), silicon dioxide (SiO2) or plastic, etc. and formed by any one method selected from the group consisting of dip coating, embossing, sputtering, evaporation, chemical vapor deposition, screen printing and pad printing. Accordingly, the first protective layer 221 and the second protective layer 222 can be respectively formed on the first sensing layer 211 and the second sensing layer 212 by any one of the methods.

After the first sensing layer 211 and the second sensing layer 212 respectively are covered by the first protective layer 221 and the second protective layer 222, the surfaces of the first sensing layer 211 and the second sensing layer 212 would not be oxidized resulting from long-time exposure to air in post-process, the surfaces and edges of the first sensing layer 211 and the second sensing layer 212 are protected from being damaged and the occurrence of optical interference phenomena is avoided.

A first electrode layer with spaced electrodes and a second electrode layer with spaced electrodes are formed by a firing process (Step 203).

The first electrode layer and the second electrode layer respectively are penetrated through the first protective layer and the second protective layer and formed on a surface of the first sensing layer and a surface of the second sensing layer (Step 204). During the formation of the first electrode layer 231 and the second electrode layer 232, a large quantity of heat or chemical substances would accompany therewith, and therefore after the first sensing layer 211 and the second sensing layer 212 respectively are covered by the first protective layer 221 and the second protective layer 222 in advance, the physical characteristics such as electrical resistance, electrical conductivity, etc. of the first sensing layer 211 and the second sensing layer 212 are not be damaged. As a result, the touch detection accuracy of the touch panel 2 is not influenced.

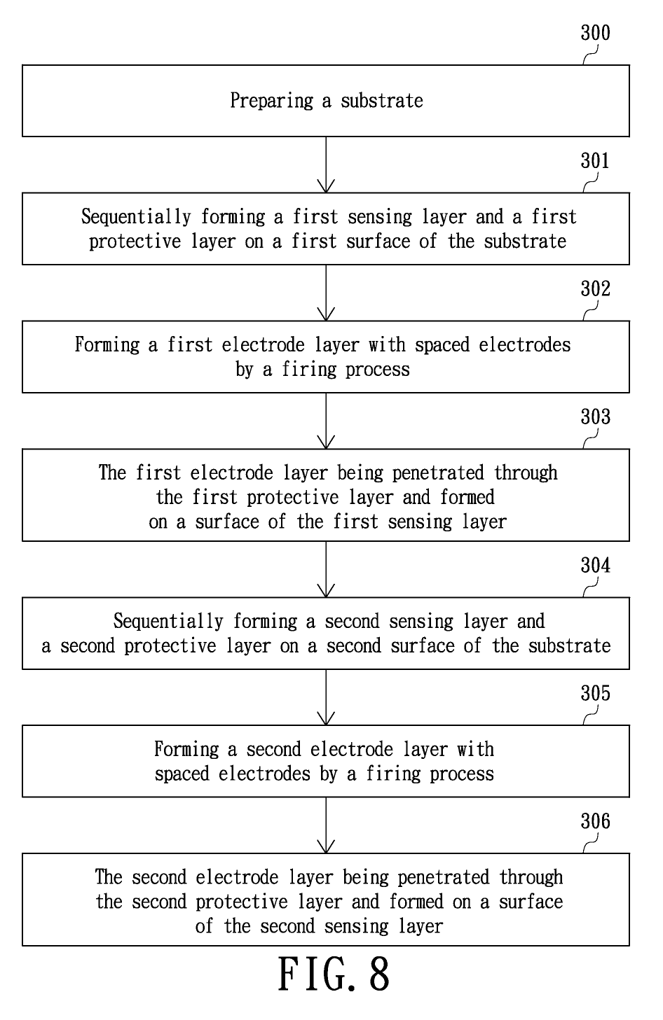

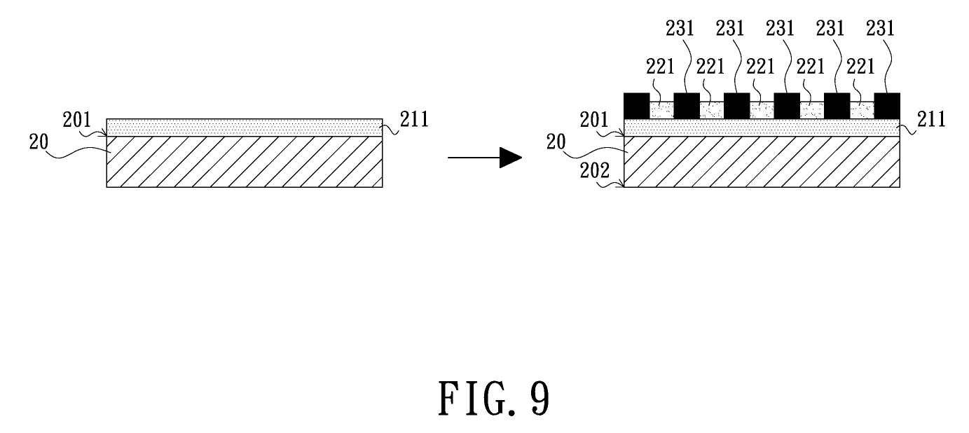

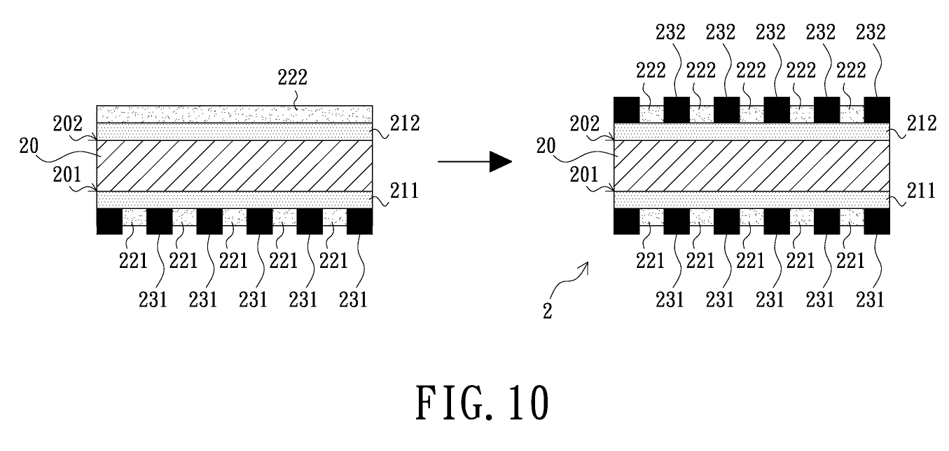

Referring to FIGS. 8 through 10, respectively illustrating a flow chart, a flow diagram (1), and a flow diagram (2) of a touch panel manufacturing method in accordance with still another preferred embodiment of the present invention. The touch panel manufacturing method in the present embodiment includes several steps as follows.

A substrate is prepared (Step 300).

A first sensing layer and a first protective layer are sequentially formed on a first surface of the substrate in that order (Step 301).

A first electrode layer with spaced electrodes is formed by a firing process (Step 303).

The first electrode layer is penetrated through the first protective layer and formed on a surface of the first sensing layer (Step 303).

A second sensing layer and a second protective layer are sequentially formed on a second surface of the substrate in that order (Step 304).

A second electrode layer with spaced electrodes is formed by a firing process (Step 305).

The second electrode layer is penetrated through the second protective layer and formed on a surface of the second sensing layer (Step 306).

As seen from above illustration, the present embodiment still illustrates a process of dual-sided manufacturing, compared with the touch panel manufacturing method as illustrated in FIGS. 5 through 7 in which: after the first sensing layer 211 and the second sensing layer 212 respectively are formed on the first surface 201 and the second surface 202 of the substrate 20, the first protective layer 221 and the second protective layer 222 are formed subsequently, and finally the first electrode layer 231 and the second electrode layer 232 are formed.

Returning to the present embodiment, the first surface 201 of the substrate 20 having the first sensing layer 211 and the first protective layer 221 sequentially formed thereon in priority, and subsequently the first electrode layer 231 is formed. A manufacturing process on the second surface 202 of the substrate 20 is started after the above manufacturing process on the first surface 201 of the substrate 20 is completed. The manufacturing process on the second surface 202 of the substrate 20 include the steps of: sequentially forming the second sensing layer 221 and the second protective layer 222 on the second surface 202 and finally forming the second electrode layer 232.

Although the touch panel manufacturing method used for dual-sided manufacturing in accordance with the present embodiment is different from the touch panel manufacturing method in accordance with the above-mentioned embodiment as illustrated in FIGS. 5 through 7, the first protective layer 221 still is formed on the first sensing layer 211 prior to the first electrode layer 231, and the second protective layer 222 still is formed on the second sensing layer 212 prior to the second electrode layer 232, and thus the same purposes and effects can be achieved. More specifically, the first sensing layer 211 and the second sensing layer 212 can be avoided to be oxidized resulting from long-time exposure to air. Meanwhile, the physical characteristics of the first sensing layer 211 and the second sensing layer 212 are not influenced during the formation of the first electrode layer 231 and the second electrode layer 232.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A touch panel manufacturing method comprising:
preparing a substrate;
sequentially forming a sensing layer and a protective layer on a surface of the substrate in that order;
forming an electrode layer with spaced electrodes by a firing process; and
the electrode layer being penetrated through the protective layer and formed on a surface of the sensing layer.

2. The touch panel manufacturing method as claimed in claim 1, wherein during the step of sequentially forming the sensing layer and the protective layer on the surface of the substrate, a method for the formation of each of the sensing layer and the protective layer is selected from the group consisting of dip coating, embossing, sputtering, evaporation, chemical vapor deposition, screen printing and pad printing.

3. The touch panel manufacturing method as claimed in claim 1, wherein the electrode layer is made of copper or aluminum.

4. The touch panel manufacturing method as claimed in claim 1, wherein the protective layer is made of one of cyclo-olefin copolymer, polyethylene terephthalate, silicon dioxide and plastic.

5. The touch panel manufacturing method as claimed in claim 1, wherein the electrode layer is comprised of electrodes in the form of electrode strips arranged in a spaced manner, or in the form of electrode blocks arranged in matrix, or in the form of electrode blocks arranged in array.

6. The touch panel manufacturing method as claimed in claim 1, wherein the sensing layer is made of indium tin oxide.

7. A touch panel manufacturing method comprising:
preparing a substrate;
forming a first sensing layer and a second sensing layer respectively on a first surface and a second surface of the substrate;
forming a first protective layer and a second protective layer respectively on the first sensing layer and the second sensing layer;
forming a first electrode layer with spaced electrodes and a second electrode layer with spaced electrodes by a firing process; and
the first electrode layer and the second electrode layer respectively being penetrated through the first protective layer and the second protective layer and formed on a surface of the first sensing layer and a surface of the second sensing layer.

8. The touch panel manufacturing method as claimed in claim 7, wherein during the step of forming the first sensing layer and the second sensing layer respectively on the first surface and the second surface of the substrate, a method for the formation of each of the first sensing layer and the second sensing layer is selected from the group consisting of dip coating, embossing, sputtering, evaporation, chemical vapor deposition, screen printing and pad printing.

9. The touch panel manufacturing method as claimed in claim 7, wherein during the step of forming the first protective layer and the second protective layer respectively on first sensing layer and the second sensing layer, a method for the formation of each of the first protective layer and the second protective layer is selected from the group consisting of dip coating, embossing, sputtering, evaporation, chemical vapor deposition, screen printing and pad printing.

10. The touch panel manufacturing method as claimed in claim 7, wherein the first electrode layer and the second electrode layer are made of copper or aluminum.

11. The touch panel manufacturing method as claimed in claim 7, wherein each of the first electrode layer and the second electrode layer is comprised of electrodes in the form of electrode strips arranged in a spaced manner, or in the form of electrode blocks arranged in matrix, or in the form of electrode blocks arranged in array.

12. The touch panel manufacturing method as claimed in claim 7, wherein the first sensing layer and the second sensing layer are made of indium tin oxide.

13. The touch panel manufacturing method as claimed in claim 7, wherein the first protective layer and the second protective layer are made of one of cyclo-olefin copolymer, polyethylene terephthalate, silicon dioxide and plastic.

14. A touch panel manufacturing method comprising:
preparing a substrate;
sequentially forming a first sensing layer and a first protective layer on a first surface of the substrate in that order;
forming a first electrode layer with spaced electrodes by a firing process;
the first electrode layer being penetrated through the first protective layer and formed on a surface of the first sensing layer;
sequentially forming a second sensing layer and a second protective layer on a second surface of the substrate in that order;
forming a second electrode layer with spaced electrodes by a firing process; and
the second electrode layer being penetrated through the second protective layer and formed on a surface of the second sensing layer.

15. The touch panel manufacturing method as claimed in claim 14, wherein during the step of sequentially forming the first sensing layer and the first protective layer on the first surface of the substrate, a method for the formation of each of the first sensing layer and the first protective layer is selected from the group consisting of dip coating, embossing, sputtering, evaporation, chemical vapor deposition, screen printing and pad printing.

16. The touch panel manufacturing method as claimed in claim 14, wherein during the step of sequentially forming the second sensing layer and the second protective layer on the second surface of the substrate, a method for the formation of each of the second sensing layer and the second protective layer is selected from the group consisting of dip coating, embossing, sputtering, evaporation, chemical vapor deposition, screen printing and pad printing.

17. The touch panel manufacturing method as claimed in claim 14, wherein the first layer electrode layer and the second electrode layer are made of metal for example copper or aluminum.

18. The touch panel manufacturing method as claimed in claim 14, wherein each of the first electrode layer and the second electrode layer is comprised of electrodes in the form of electrode strips arranged in a spaced manner, or in the form of electrode blocks arranged in matrix, or in the form of electrode blocks arranged in array.

19. The touch panel manufacturing method as claimed in claim 14, wherein the first sensing layer and the second sensing layer are made of indium tin oxide.

20. The touch panel manufacturing method as claimed in claim 14, wherein the first protective layer and the second protective layer are made of one of cyclo-olefin copolymer, polyethylene terephthalate, silicon dioxide and plastic.
